(19) United States
(12) Patent Application Publication
(10) Pub. No.: US 2024/0334668 A1
(43) Pub. Date: Oct. 3, 2024

(54) PREDICTING TIMES FOR PICK AND PLACE MATERIAL REPLENISHMENT FOR A PICK AND PLACE LINE

(71) Applicant: ASMPT GmbH & Co. KG, Munich (DE)

(72) Inventors: Bastian KNOBLECHNER, Munich (DE); Matthias MIKSCH, Munich (DE); Vincent PFEIFER, Munich (DE)

(21) Appl. No.: 18/612,020

(22) Filed: Mar. 21, 2024

(30) Foreign Application Priority Data
Mar. 28, 2023 (DE) 10 2023 107 885.2

(51) Int. Cl. H05K 13/08; H05K 13/02; H05K 13/04

(52) U.S. Cl. CPC H05K 13/086; H05K 13/0495; H05K 13/084; H05K 13/021

(57) ABSTRACT

A method and a pick and place line for predicting a time for replenishing pick and place material (C) comprises (a) detecting a current filling level of component material from a first component feeder; (b) determining the planned pick and place operations which are still required in order to populate all component carriers (PCB) of a current batch production in a first pick and place station; (c) determining a position of a component carrier along the transport path which has been populated in a second pick and place station and which is still to be populated in the first pick and place station; and (d) predicting the time for replenishing pick and place material at the first feed track based on the detected current filling level, the determined planned populated operations and the determined current position.

### TECHNICAL FIELD

The present invention relates in general to the manufacture of electronic assemblies by means of a pick and place line, which comprises at least one and typically several pick and place machines connected in series. The present invention relates in particular to (i) a method for predicting a time for replenishing pick and place material for a first pick and place station of a pick and place line, (ii) a method for predicting times for replenishing pick and place material at different predetermined feed tracks of at least one pick and place station of a pick and place line, (iii) a method for determining a chronological order for a replenishment of pick and place material in at least two feed tracks of a pick and place line, and (iv) a pick and place line with a data processing device which is configured to execute the said methods or to control their sequence.

### BACKGROUND OF THE INVENTION

Component carriers such as printed circuit boards or substrates are populated with electronic components using pick and place machines. A pick and place machine has a pick and place head which (i) picks up electronic components at a pick-up position of a component feeder, (ii) transfers them to a pick and place area of the pick and place machine in which the component carrier to be populated is located, and (iii) places the picked-up component on the component carrier at a predetermined pick and place position.

In order to produce electronic assemblies consisting in each case of one component carrier and a plurality of different types of components, the component carrier in question is typically populated with several pick and place machines. Several component feeders are thereby assigned to each pick and place machine, with which different types of electronic components are fed to the pick and place process.

The pick and place machines used for manufacturing assemblies are typically arranged one behind the other in a pick and place line and the component carrier is transported through the pick and place areas of the various pick and place machines by means of a transport device. The respective component carrier is then in each case at least partially populated in different pick and place areas.

In order to ensure that the pick and place line operates with as few interruptions as possible, it must be ensured that there is always a sufficient amount of pick and place material or a sufficient number of components for each component feeder. This can be done in different ways (A) and (B):

### (A) Monitoring of a Threshold Value

With this variant, a current filling level of pick and place material is assigned to each individual component feeder at any time. If components are populated, the filling level is updated. The consumption of pick and place material for an optimally operating pick and place line can be predicted using software. If the material falls below certain threshold values, an order is generated to replenish pick and place material at the component feeder in question. This order is then carried out by an operator or a robot, which transfers new pick and place material to the component feeder in question.

### (B) Calculating the Pick and Place Material Requirement

This is done by means of a software-supported logistics workflow solution, which ensures and monitors a continuous supply of pick and place material on a pick and place line. Based on the planned and actual material consumption and the current material stock on the pick and place line, the required electronic components, which are packed in a component belt, are picked in a central material warehouse. This picking process involves winding a component belt of a suitable length onto a belt reel. Alternatively, a belt reel with an already wound component belt can be delivered to the central material store by a manufacturer or dealer. The quantity determination and transfer of a required picked belt reel to the pick and place line, for example, takes place in an hourly cycle. The actual replenishment process on the pick and place machines in question, or more precisely on the component feeder in question, is not monitored.

A continuous supply of pick and place material at the component feeders currently involves so-called splicing. In a splicing process, the end of a component belt, which is about to be used up due to the removal of components, is connected to the beginning of a new component belt by means of a connecting element. In this way, the component belt that is about to be used up is extended and a continuous supply of pick and place material is ensured. Splicing is typically carried out manually by an operator. To prevent a component feeder from becoming empty, the operator only has a limited amount of time in which to carry out or complete the splicing process.

In order to automate a component replenishment process, component feeders with a housing containing the belt reel are known. A component or material replenishment process on a so-called component feed track of a pick and place machine is then carried out by replacing the entire component feeder, which can be carried out automatically by a robot. To prevent a pick and place machine from coming to a standstill, it is necessary to change a component feeder as soon as it is emptied. A precise prediction is therefore required that predicts the time of such a change as accurately as possible. Only then is it possible to operate a pick and place line at a high level of efficiency without prolonged downtimes of at least some of the pick and place machines.

The invention is based on the object of improving the efficiency of pick and place lines whose pick and place machines are fed pick and place material, in particular in an automated manner.

### SUMMARY OF THE INVENTION

This object is achieved by the subject matter of the independent claims. Advantageous embodiments of the present invention are described in the dependent claims.

According to a first aspect of the invention, a method is described for predicting a time for replenishing pick and place material for a first pick and place station of a pick and place line comprising at least (i) the first pick and place station which is supplied with pick and place material at a (selected) first feed track by a first component feeder and (ii) a second pick and place station which is supplied with pick and place material at a second feed track by a second component feeder, the second pick and place station being arranged upstream of the first pick and place station along (a predetermined direction of transport) a transport path for component carriers to be populated. The method described features (a) detecting a current filling level of component material from the first component feeder; (b) determining the planned pick and place operations, at least with the component material assigned to the first feed track, which population operations are still required in order to populate all component carriers of a current batch production in the first pick and place station; (c) determining a current position of at least one component carrier along the transport path which has been populated in the second pick and place station and which is still to be populated in the first pick and place station; and (d) predicting the time for replenishing pick and place material at the first feed track based on (d1) the detected current filling level, (d2) the determined planned populated operations and (d3) the determined current position.

The method described is based on the realization that the prediction of the time at which pick and place material must be replenished at the first feed track is based not only on information about the ideal operation of the pick and place line, but also on information about the current actual operation of the pick and place line. The current real operation is characterized by more or less major disruptions compared to the idealized pick and place operation, which cause a deviation from the idealized pick and place operation. The method according to the invention can thus determine the time for replenishing pick and place material with a greater accuracy than would be possible with a known method in which only the operating states for an ideal pick and place operation are taken into account.

With the method described, it can be ensured that a pick and place line with several pick and place stations and typically several component feeders per pick and place station is always supplied with sufficient pick and place material, even in practical or real operation, so that unwanted downtimes of the pick and place line can be prevented. Specifically, by accurately predicting the times at which a replenishment of pick and place material is required at the respective feed track, it can be ensured that a sufficient supply of pick and place material is on site in good time.

Sufficient pick and place material can be provided manually by an operator. Alternatively, or for selected feed tracks, the pick and place material can also be provided by a robot prior to replenishment. By accurately predicting the replenishment times for different and preferably all feed tracks, a sequence for replenishing the pick and place material at the different feed tracks can also be determined. This makes it possible to prioritize the replenishment of the pick and place material at those feed tracks that are next “threatened” by depletion of the currently available pick and place material. Furthermore, feed tracks at different pick and place stations can also be prioritized depending on the occupancy or utilization of buffer areas with temporarily stored component carriers, which are provided in a known manner along the transport path before and/or after a pick and place area of a pick and place station. Thus, for example, the feed stations of a pick and place area, in front of which many component carriers have accumulated, can be assigned a higher priority. This allows unwanted congestion to be cleared as quickly as possible. These considerations apply in particular to an automated replenishment of pick and place material by means of at least one robot, which collects the new pick and place material from an (intermediate) store and transports it to the respective feed track.

Furthermore, travel paths can also be optimized for robots that can transport several types of pick and place material at the same time. Thus, for example, replenishment of the first pick and place material, which is actually required next, can be postponed if there is still sufficient time until the corresponding predicted time to carry out a less urgent replenishment of the second pick and place material on another feed track in the meantime. Both the prioritization and the optimization of transport routes described above can of course also be carried out by an operator during manual replenishment of pick and place material.

A deviation from the idealized pick and place operation can be caused by a variety of different minor or major disruptions. Minor disruptions in particular can often be rectified independently and automatically by the pick and place line or the corresponding pick and place machines. Such minor faults include, for example, a loss of a component to be populated, in particular due to a failed component pick-up at a component pick-up position and/or due to a non-optimal (negative) suction pressure at the tip of a component holding device designed as a suction gripper on a pick and place head. A major disruption, which can typically only be eliminated by corrective intervention by an operator, is, for example, a tear in a cover foil of a component belt in which components are held in a known manner in so-called holding pockets and are fed to a component pick-up position. Such a cover foil is removed in a likewise known manner immediately before the planned pick-up of a component at the relevant component pick-up position, so that a pick and place head or, more precisely, a suction gripper of a pick and place head can access the component to be picked up from above. A disruption to pick and place operation can also result, for example, from the (accidental or necessary) opening of a protective cover of at least one pick and place station. For safety reasons, such an opening leads to a stop of the pick and place operation of the pick and place station(s) concerned.

It is pointed out that a disruption does not necessarily lead to a delay in pick and place operation. A disruption can also arise, for example, if it becomes apparent before or during population of a larger component carrier, which has several so-called individual panels, that (at least) one individual panel can no longer be populated in a meaningful way. This can be due, for example, to the fact that the component carrier is damaged, especially in the area of the individual panel in question, so that further processing and, in particular, further population of this individual panel no longer makes sense. As this means that not all individual panels are populated for this specific component carrier, the component carrier can be populated more quickly. The component carrier can therefore be transferred from one pick and place station along the transport path to the next pick and place station earlier than in an idealized pick and place operation.

The two pick and place stations described can be directly adjacent along the transport path, i.e., directly following one another from the perspective of a transported component carrier. Alternatively, the two pick and place stations can also be spaced further apart, with a further pick and place station or another station on the pick and place line being arranged between the second pick and place station and the first pick and place station. One such other station can, for example, be a measuring station by means of which a successful pick and place operation in the second pick and place station is optically detected, whereby the measurement result of such a measuring station can, for example, be used for quality monitoring of the pick and place operation.

The second pick and place station can be any selected pick and place station of the pick and place line except for the last pick and place station along the transport path. In the context of the description used here, the first pick and place station can be any selected pick and place station (including the last pick and place station of the pick and place line) as long as it is located downstream of the second pick and place station. From the point of view of a component carrier transported along the transport path, population in the second pick and place station therefore takes place before population in the first pick and place station.

The method according to the invention is described in this document (as a rule) from the point of view of the downstream first pick and place station and, more precisely, from the point of view of a selected first feed track or a (selected) first component feeder assigned to the selected first feed track. However, it is pointed out that the method described can also be carried out (simultaneously) for at least one further first feed track or a further first component feeder of the first pick and place station assigned to the further first feed track. This means that not only the replenishment times at the first feed track can be predicted, but in principle also the replenishment times at all other first feed tracks of the first pick and place station. This enables comprehensive and accurate prediction of replenishment times at several and preferably all first feed tracks of the first pick and place station.

It is pointed out that in a pick and place line with at least three pick and place stations arranged along a transport path, wherein a third pick and place station, which is supplied with pick and place material at (at least) a third feed track by a third component feeder, is arranged upstream of the second pick and place station, the method described can also be carried out from the viewpoint of at least one of the second feed tracks of the second pick and place position. In this case, the filling level of the relevant second component feeder is then (additionally) detected. Furthermore, the planned pick and place operations that are still required to populate all component carriers of the current batch production in the second pick and place station are (additionally) determined.

Furthermore, the current position of at least one component carrier along the transport path is (additionally) determined, which was populated in the third pick and place station and which still has to be populated in the second pick and place station (and in the first pick and place station). This means that the replenishment times of pick and place material can in principle be predicted with a high degree of accuracy for a pick and place line for all feed tracks with the exception of those feed tracks that are assigned to the pick and place station in which the population of the component carriers by the pick and place line begins.

To put it clearly, the prediction of at least one “pick and place material replenishment time” according to the invention takes into account the “reality” of the pick and place operation by identifying a possible congestion relating to the transport along the transport path by determining the current position of (at least) one component carrier, which still has to be populated by the respective (first) pick and place station arranged downstream. In this context, it is obvious that such a congestion can only be resolved and/or an aggravation of the congestion can only be prevented if the further transport of the component carrier is not also hindered by a delay at the first pick and place station arranged downstream, whereby such a delay would be caused in an obvious manner by a delayed replenishment of pick and place material.

Detecting the filling level of pick and place material from the (selected) first component feeder can be carried out in a known manner using suitable sensors. Alternatively, or in combination, the filling level can also be detected by a (central) machine control system of the relevant pick and place station or the entire pick and place line, which controls or coordinates the pick and place operation and usually knows the filling levels of all component feeders currently in use.

Determining the pick and place operations still required for the current batch production with the pick and place material assigned to the first feed track can also be carried out by a machine control system, in particular a machine control system for the entire pick and place line. In this context, the number of pick and place operations still required is particularly important, as this is indicative of how much pick and place material is still required on the (selected) first feed track for the current batch production. To put it clearly, by determining the (number of) planned pick and place operations as described above, a prognosis is made with regard to the expected consumption of pick and place material, which is of course of decisive importance for a reliable prediction of the replenishment time.

In this document, the term “pick and place operation” is understood to mean in particular the population of a component. This comprises (i) picking up the component by means of a component holding device of a pick and place head from a component pick-up position, (ii) transporting the picked-up component to a pick and place area of the pick and place station concerned, (iii) placing the transported component on the relevant component carrier at a predetermined pick and place position, and (iv) moving the pick and place head back to the component pick-up position or to an adjacent component pick-up position of a component feeder system having a plurality of component feeders, so that a next component can be picked up for a next pick and place operation.

In this document, the term “pick and place station” refers to a single pick and place machine. In the case of a larger pick and place machine, a pick and place station can also be a part of the pick and place machine with its own pick and place area, whereby the pick and place area is typically assigned at least one pick and place head which can be moved between (i) component pick-up positions and (ii) a component carrier held in the pick and place area by means of a gantry system.

In this document, the term “batch production” refers in particular to the population or manufacture of component carriers of a specific type, which are to be populated in the pick and place line (as a whole) as part of a production batch and/or with a specific population order.

The current position of at least one component carrier along the transport path, which has been populated in the second pick and place station and which is still to be populated in the first pick and place station, can also be determined by means of suitable sensors and/or by means of a (central) machine control system. In other words, the position of an at least partially populated component carrier or the positions of several at least partially populated component carriers is determined, which are located upstream of the selected first pick and place station relative to the direction of transport.

The position determination described above provides information on how long it will take until the next component carrier can be or is fed to the first pick and place station. The next component carrier is the component carrier whose population has already been completed in the second pick and place station and which can therefore be fed to the first pick and place station and which is also fed without a congestion of component carriers (at the first pick and place station) during optimum pick and place operation.

According to one embodiment of the invention, the pick and place material has electronic components, which are held in particular in a component belt or in a component magazine. The component magazine can have the structure of a two-dimensional array, in which a plurality of magazine pick-up areas are spatially arranged along two preferably mutually perpendicular axes. The component magazine can also have the structure of a one-dimensional array, in which several magazine pick-up areas are arranged along a longitudinal direction of the magazine.

Storing the electronic components in a component belt and feeding the electronic components to a pick and place head, which can pick up one component at a time directly from a receptacle or pocket of the component belt with a component take-up process, has the advantage that the filling level of the relevant pick and place material can be detected in a particularly reliable manner. Compared to feeding components as bulk material, the components in a component belt are reliably separated in a known manner, so that the components used so far and, if the number of components initially present in the component belt is known, the number of components still present in the component belt in question or the amount of pick and place material not yet used can be easily detected.

According to a further embodiment of the invention, the method further comprises determining a batch size of the current batch production, wherein predicting the time for replenishing pick and place material at the first feed track is further based on the determined batch size.

In this document, the term “batch size” refers in particular to the number of component carriers to be populated in the current batch production. The batch size can be the total number of component carriers that are (or are to be) populated as part of a production batch and/or with a specific population order. Alternatively, however, the term “batch size” can also be understood as the number of component carriers that still need to be populated after the start of the current batch production, whereby the batch size then changes continuously as the current batch production progresses.

The batch size is a very easy to determine variable that characterizes the operation of the pick and place line. Taking the batch size into account for predicting the replenishment time contributes to a high prediction accuracy of the predicted replenishment time(s), especially at the beginning or in an early phase of the current batch production. In this context, it should be mentioned that pick and place material may also have to be replenished at the start of batch production because a larger quantity of pick and place material is not always provided at the start of the feed tracks. This is because batch production often begins, at least on individual feed tracks, with residual pick and place material that is still left over from a previous batch production run and should of course be used up for cost reasons.

According to a further embodiment of the invention, the method further comprises determining a length of time for transporting the at least one component carrier, which has been populated in the second placement station and which is still to be populated in the first placement station, from the second placement station to the first placement station, wherein predicting the time for replenishing pick and place material at the first feed track is further based on the determined length of time.

The length of time for the described component carrier transport is also a significant factor for the expected replenishment time. It in fact directly describes the “arrival” of the component carrier in question in or at the first pick and place station. Consequently, taking them into account can contribute to (further) improving the accuracy of the replenishment time prediction.

The described length of time can be determined, for example, using sensors that optically detect other component carriers for example, which are located between the relevant component carrier and the first pick and place station on the transport path. In this context, it is obvious that at least one such other component carrier hinders the transport of the component carrier in question to the first pick and place station because the component carrier in question has to “get in line”.

According to a further embodiment of the invention, the method further comprises replenishing pick and place material at the (selected) first feed track in time (or in good time) before the predicted time. This ensures that there is always (a sufficient amount of) pick and place material on the selected feed track.

As already explained above, the method according to the invention is described in this document essentially from the point of view of one or the selected first feed track of the first pick and place station. However, the method according to the invention can also be carried out (simultaneously) for other feed tracks of the first feed track or also for other feed tracks of other pick and place stations, whereby it is only necessary that the described determination of the current position of at least one (partially populated) component carrier along the transport path relates to a component carrier located upstream, which is still to be (further) populated in the (downstream) first feed track. Thus, the replenishment described here can also refer to all possible feed tracks from all possible pick and place stations of the pick and place line with the exception of the pick and place station which is located along the direction of transport directly or at the very beginning of the transport line.

According to a further embodiment of the invention, replenishing the placement material comprises (a) removing the first component feeder from the first transport track, wherein any remaining unused pick and place material is removed together with the first component feeder; and (b) attaching another first component feeder together with new pick and place material to the (selected) first feed track, wherein the new pick and place material is located in or on the other first component feeder.

The described replenishment of pick and place material associated with a replacement of the component feeder has the advantage that the replenishment can be realized in a simple and error-tolerant manner. Compared to a replenishment in which the (selected first) component feeder remains on the (selected first) feed track and in which the pick and place material is, for example, only in the form of a component belt wound on a belt reel, replacement of the complete component feeder does not require, for example, manual and error-prone threading of the beginning of the component belt into a guide channel of the component feeder in question, which in practice often has to be carried out by an operator under great time pressure in order to ensure an uninterrupted supply of pick and place material to the entire placement line. A component feeder, to which or in which pick and place material is attached or held, can be pre-assembled in advance in an (intermediate) warehouse of a production hall, so that the replacement of a component feeder with pick and place material can be carried out not only particularly reliably but also particularly quickly.

According to a further embodiment of the invention, the removal of the first component feeder and the attachment of the other first component feeder is automated by means of a robot.

The automated replacement of the component feeder described above can significantly reduce the manual operating effort required to operate a pick and place line. As a result, the manufacturing costs of electronic assemblies can be reduced in an advantageous way.

According to a further embodiment of the invention, the method further comprises determining a further current position of at least one further component carrier along the transport path, which has been populated in a third pick and place station and which is still to be populated in the first pick and place station and/or the second pick and place station. The third pick and place station is thereby arranged along the transport path upstream from the second pick and place station. In addition, predicting the time for replenishing pick and place material at the first feed track is also based on the determined further current position.

The described inclusion of the position of at least one further component carrier, which is located along the direction of transport behind the (at least one) first component carrier described above, enables a particularly comprehensive picture of the current “component carrier congestion” in front of or upstream of the first pick and place station. As a result, a particularly high level of accuracy can be achieved in predicting replenishment times at the (selected) first feed track of the (selected) first pick and place station.

According to a further aspect of the invention, a method for predicting (at least two) times for replenishing pick and place material at different predetermined feed tracks of at least one pick and place station of a pick and place line is described, which has a plurality of pick and place stations which are arranged in succession along (in a predetermined direction of transport) a transport path of the pick and place line for component carriers to be populated. The method described is carried out (separately) for two different feed tracks. Accordingly, the described method comprises, on the one hand, performing the method described above, wherein the first feed track is a first predetermined feed track of the pick and place line and the predicted time is a first replenishment time associated with the first predetermined feed track. The described method comprises, on the other hand, performing the method described above, wherein (now) the first feed track is a second predetermined feed track of the pick and place line and the predicted time is a second replenishment time associated with the second predetermined feed track.

The method described for predicting at least two replenishment times is based on the realization that an uninterrupted supply of pick and place material can be ensured at several predetermined feed tracks and preferably at all feed tracks of the pick and place line, as long as it is ensured that replenishment of pick and place material takes place at all relevant feed tracks in good time, i.e., before the respective determined replenishment time. This ensures a continuous supply of pick and place material along the entire pick and place line with high reliability and minimizes unwanted downtimes of the pick and place line or even just sections of the pick and place line.

According to a further embodiment of the invention, the method further comprises determining a chronological order for (i) replenishing pick and place material at the first predetermined feed track and (ii) replenishing pick and place material at the second predetermined feed track based on the first replenishment time and the second replenishment time. The logistics of supplying the pick and place line with pick and place material can be optimized by determining the chronological order of at least two “replenishments” as described. This applies not only to automatic replenishments of pick and place material using at least one robot, but also to manual replenishments by at least one operator.

According to a further embodiment of the invention, the determined chronological order establishes a priority according to which the pick and place material (from the first predetermined feed track and the second predetermined feed track) is first replenished at the predetermined feed track to which the earlier replenishment time (of the first replenishment time and the second replenishment time) is assigned. The described prioritization of the replenishment is particularly relevant for the reliable provision of pick and place material if it does not take long to reach at least the earlier replenishment time and/or if the two replenishment times are close together. In this case, speed is of the essence so as not to miss the earlier replenishment time.

According to a further embodiment of the invention, the first replenishment time is prior to the second replenishment time and the described method further comprises (a) replenishing pick and place material at the second predetermined feed track and thereafter (b) replenishing pick and place material at the first predetermined feed track. This kind of temporal inversion of the determined chronological order with respect to the corresponding replenishments or replenishment procedures at the various predetermined feed tracks can be carried out in particular if it still takes a comparatively long period of time until the two replenishment times are reached. One advantage of the described temporal inversion can be seen, for example, in the fact that in some operating scenarios, travel distances for robots for the automatic replenishment of pick and place material or also walking distances of operators who manually carry out the replenishment of pick and place material can be shortened. This can apply in particular if the robot or operator in question can simultaneously transport two types of pick and place material to the respective predetermined feed track. Thanks to the described inversion, the entire logistics of an uninterrupted supply of pick and place material can be realized more efficiently, at least in some operating scenarios. A further advantage of the described temporal inversion in many cases that arise in practice can also be that an unwanted congestion of component carriers in an intermediate store, which is provided along the transport path before a pick and place area, can be resolved as quickly as possible.

It is pointed out that for an actual replenishment of pick and place material, changing the determined chronological order to an inversion or from an inversion back to the prioritization described above according to predicted replenishment times can be carried out in particular at a time before a robot for automatic replenishment of pick and place material leaves an (intermediate) store of pick and place material. In some operating scenarios, the chronological order can also be changed at a later point in time, i.e., when the robot is already on its way to a feed track. To put it clearly, this means that a change in the specific chronological order causes the respective robot to change its route for and/or the sequence of replenishments “underway” while it is transporting pick and place material.

According to a further aspect of the invention, a method is described for determining a chronological order for replenishing pick and place material on at least two feed tracks of a pick and place line which has at least two pick and place stations for populating component carriers, wherein each pick and place station has a pick and place area and at least two buffer areas for buffering component carriers, wherein the pick and place areas and the buffer areas are arranged along (a predetermined direction of transport) a transport path of the pick and place line and wherein each pick and place area upstream (i.e., opposite the direction of transport) is assigned in each case one of the two buffer areas. The method described by this aspect of the invention comprises (a) detecting an occupancy state of at least one buffer area of the two buffer areas; and (b) determining the chronological order based (inter alia) on the at least one detected occupancy state.

This described method is based on the realization that a component carrier occupancy state (in addition to other current operating state variables) of a buffer area arranged upstream in the transport path is an important indicator of when a next component carrier can be started in the next (downstream) pick and place station after a previous component carrier has been populated. The time at which populating the next component carrier begins naturally has an influence on the consumption of pick and place material and thus on the time at which new pick and place material must be made available at the relevant feed track at the latest in order to prevent an undesired lack of pick and place material and thus an interruption of the pick and place operation, at least at the relevant pick and place station.

The specific order can determine a priority of actual replenishment. However, as described above, the specific chronological order for the actual replenishment can also be changed or inverted.

A buffer area within the meaning of the technology described in this document can be any configuration of an intermediate store for component carriers. The component carrier occupancy state of a buffer area can be detected using suitable (optical) sensors, for example. Alternatively, or in combination, the current component carrier occupancy state can also be monitored and/or controlled and (then) output by a control system of the relevant pick and place station and, in particular, by a central control system of the entire pick and place line.

According to a further embodiment of the invention, the described method further comprises detecting a current filling level of pick and place material at each of the at least two feed tracks, wherein the determination of the chronological order is further based on the detected current filling levels.

As described above, detecting the filling levels can be carried out by suitable sensors of or on a relevant component feeder. Alternatively, or in combination, the filling level can also be detected by a (central) machine control system of the relevant pick and place station or the entire pick and place line, which controls or coordinates the pick and place operation and usually knows the filling levels of all component feeders currently in use.

According to a further embodiment of the invention, the method further comprises (a) determining the planned pick and place operations which are still to be carried out with at least that pick and place material which is assigned to at least one feed track of the at least two feed tracks in order to populate all component carriers of a current batch production.

When determining the planned pick and place operations as described, the number of pick and place operations that are still required until completion of the current batch production can be determined in particular. As a result, the chronological order for pick and place material replenishment can be determined with a particularly high degree of reliability. For example, it is possible to avoid the unnecessary replenishment of pick and place material if the filling level of batch production is low and the current batch production is almost complete and (before switching to the next batch production) pick and place material is provided that is no longer required for the current batch production and is not required at all for the next batch production. Generally speaking, any unnecessary replenishment of pick and place material can be efficiently prevented.

According to a further aspect of the invention, a pick and place line for automatically populating component carriers with electronic components is described, which are fed as pick and place material to individual pick and place stations of the pick and place line at feed tracks by means of a component feeder in each case. The pick and place line described comprises (among other things) a data processing device which is configured (programmed) to carry out one of the methods described above.

The pick and place line described is also based on the realization that the data processing device takes into account not only information about the ideal operation of the pick and place line but also information about the current actual operation of the pick and place line in order to predict the time at which pick and place material must be replenished on at least one feed line. The current real operation is characterized by more or less major disruptions compared to the idealized pick and place operation, which cause a deviation from the idealized pick and place operation. This makes it possible to determine the time for replenishing pick and place material for a selected feed track or for several selected feed tracks with a greater accuracy than would be possible with a known pick and place line (without the data processing device according to the invention), in which only the operating states for an ideal pick and place operation are taken into account for predicting pick and place material replenishment times.

The data processing device described can be part of a (central) control device of the pick and place line or at least one pick and place station.

The data processing device can be realized by means of software, hardware or a combination of software and hardware.

It is pointed out that embodiments of the invention have been described with reference to different objects of the invention. In particular, some embodiments of the invention are described with device claims and other embodiments of the invention with procedural claims. However, when reading this document, it is immediately clear to the person skilled in the art that, if not otherwise explicitly stated, in addition to a combination of features belonging to one type of object of the invention, any combination of features belonging to different types of objects of the invention is possible.

Further advantages and features of the present invention arise from the following exemplary description of currently preferable embodiments.

### BRIEF DESCRIPTION OF THE DRAWINGS

FIG. 1 shows a block diagram of an automated supply of a pick and place line with pick and place material comprising components held in component belts, the component belts each being contained in a component feeder.

FIG. 2 shows the operation of a robot for transferring component feeders filled with pick and place material from an intermediate store to a pick and place line and for transferring component feeders at least partially emptied of pick and place material back to the intermediate store.

FIG. 3 shows a pick and place line with three successively connected pick and place stations, each of which has a pick and place area and two buffer areas for intermediate storage of component carriers.

FIGS. 4a and 4b illustrate the transport of component carriers in an ideal operation of a pick and place line or in a real operation of a pick and place line that regularly occurs in practice.

FIG. 5a shows a flow chart of a calculation of the time when the pick and place material available at a pick and place station will (presumably) be used up. FIG. 5b shows a flow chart of a calculation of the time when a next component carrier will (presumably) be present in a pick and place area of a pick and place station.

FIGS. 6a and 6b illustrate the transport of component carriers in an ideal operation of a pick and place line or in a real operation of a pick and place line, in which component carriers are congested in buffer areas in front of a pick and place station.

FIGS. 7a and 7b illustrate a sensible change in the sequence for replacing component feeders for a pick and place line with four pick and place stations based on a comparison with an ideal pick and place operation for a real operation of the pick and place line (with a disrupted transport of component carriers).

FIGS. 8a and 8b illustrate a sensible retention of the sequence for replacing component feeders for a pick and place line with four pick and place stations based on a comparison with an ideal pick and place operation for a real operation of the pick and place line.

### DETAILED DESCRIPTION

It is pointed out that, in the following detailed description, features or components of different embodiments that are identical or at least functionally identical to the corresponding features or components of another embodiment are provided with the same reference numerals or with reference numerals that are identical in the last two digits of the reference symbols of corresponding identical or at least functionally identical features or components. To avoid unnecessary repetitions, features or components that have already been explained on the basis of a previously described embodiment are no longer explained in detail at subsequent points.

Furthermore, it is noted that the following described embodiments only represent a limited selection of possible variations of embodiments of the invention. In particular, it is possible to combine the features of individual embodiments in a suitable manner, such that a multitude of different embodiments can be viewed as obviously disclosed for the person skilled in the art with the embodiments explicitly described here.

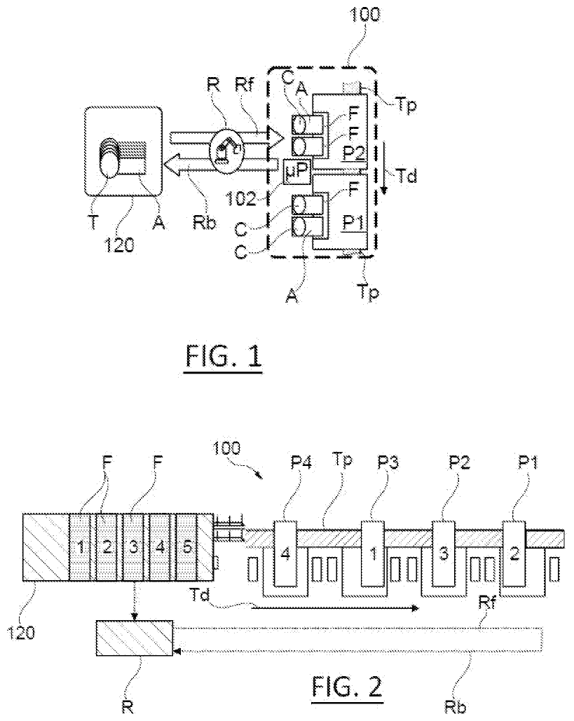

FIG. 1 shows a block diagram of an automated supply of a pick and place line 100 with pick and place material C, which comprises electronic components. The electronic components are held in a known manner in component belts not shown in detail and are fed to a pick and place process by means of a component belt and a suitably designed component feeder F on a so-called feed track. According to the embodiment shown here, a component belt is held in a pick-up area A of a component feeder F. If a component belt has been emptied by successive removal of electronic components, the component feeder F in question must be replaced at the latest by a new component feeder F containing new pick and place material C in the form of a component belt that has not yet been used up.

The pick and place line 100 has several pick and place stations. According to the embodiment shown here, the pick and place line 100 has two pick and place stations, a first pick and place station P1 and a second pick and place station P2. The two pick and place stations P1 and P2 are connected to each other via a transport path Tp, on which component carriers or printed circuit boards not shown in FIG. 1 can be transferred along a direction of transport Td from the second pick and place station P2 to the first pick and place station P1. This means that the second pick and place station P2 is arranged upstream of the first pick and place station P1 with respect to the direction of transport Td. In the embodiment shown here, a component carrier can thus first be (partially) populated with a set of electronic components in a known manner by means of the second pick and place station P2. After such a partial population, the component carrier can then be populated with another set of electronic components by means of the second pick and place station P2.

Of course, further pick and place stations can be arranged along the transport path Tp, which can make a further contribution to the population of the component carrier. In the embodiments described below with more than two pick and place machines, populating a component carrier begins with a third pick and place station or with a fourth pick and place station.

The pick and place operation by means of the pick and place line 100 is controlled by a data processing device 102. The data processing device 102 can directly control the individual pick and place stations P2, P1. Alternatively, or in combination, the data processing device 102 may also be a higher-level data processing device which controls the pick and place operation by the individual pick and place stations P2, P1 via subordinate data processing devices of the pick and place stations P2, P1.

According to the embodiment shown here, an “old” component feeder whose pick and place material has been at least almost used up is replaced automatically by a “new” component feeder with “fresh” pick and place material by means of a robot R. The robot R removes “new” component feeders filled with pick and place material from an intermediate store 120 and transports them to the pick and place station P2 or P1, at which the relevant “old” component feeder F, which has been at least almost emptied of pick and place material, is located on a feed track of the pick and place station. Having arrived at the relevant pick and place station P2/P1, the robot R then removes the “old” component feeder F from the feed track assigned to it and attaches the “new” component feeder F to the relevant feed track of the pick and place station P2, P1. In FIG. 1, the outward path of the robot R from the intermediate store 120 to the pick and place line 100 is indicated by an arrow Rf. The return path from the pick and place line 100 to the intermediate store 120 is indicated by an arrow Rb. It is pointed out that the robot R can also transport several “new” component feeders F along the outward path Rf. The same applies to the return path Rb, on which the robot R can transport several “old” component feeders F back to the intermediate store 120.

FIG. 2 shows the operation of a robot R for automatically supplying a pick and place line 100 with pick and place material. According to the embodiment shown here, the pick and place line 100 comprises four pick and place stations, a fourth pick and place station P4, a third pick and place station P3, a second pick and place station P2 and a first pick and place station P1. The transport path of a component carrier not shown to be populated on the transport path Tp along the direction of transport Td thus runs from the fourth pick and place station P4 via the third pick and place station P3 and the second pick and place station P2 to the first pick and place station P1.

The robot R transfers “new” component feeders F filled with pick and place material from the intermediate store 120 shown to a pick and place line 200. This takes place along an outward path Rf. Furthermore, the robot R transfers “old” component feeders F, whose pick and place material has been at least largely used up, back from the pick and place line 200 to the intermediate store 120. This takes place along a return path Rb. The robot F is preferably configured in such a way that it can hold several feeding devices F. This means that it can replace several “old” feeding devices F with “new” feeding devices F on one feed track of each of the different pick and place stations P4, P3, P2 and P1 in one large transport or operation.

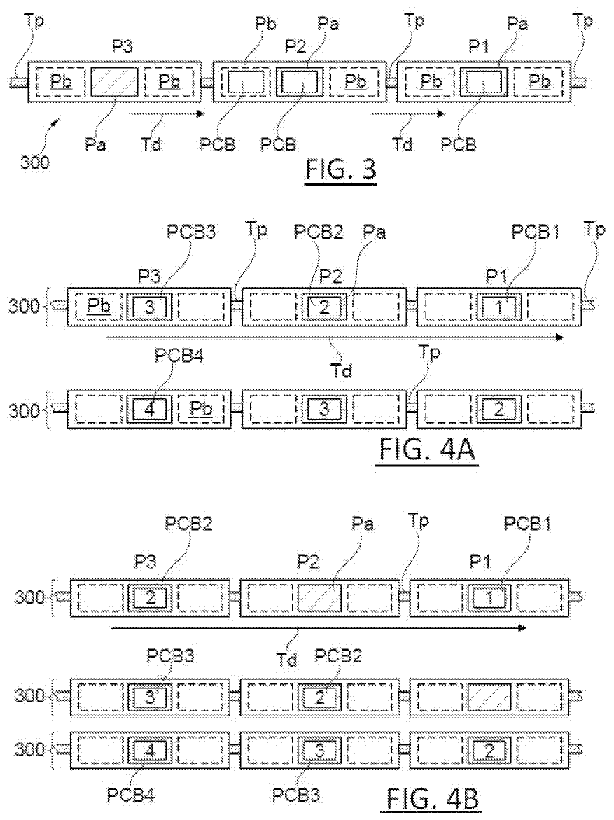

FIG. 3 shows a pick and place line 300 with three successively connected pick and place stations P3, P2 and P1. Each of the three pick and place stations P3, P2, P1 has a pick and place area Pa and two buffer areas Pb for intermediate storage of component carriers PCB. According to the embodiment shown here, one of the two buffer areas Pb is arranged upstream of the pick and place area Pa along the direction of transport Td in each of the three pick and place stations P3, P2, P1 and the other of the two buffer areas Pb is arranged downstream of the pick and place area Pa.

In the operating state of the pick and place line 300 shown in FIG. 3, a congestion of the transport of a component carrier PCB has occurred in front of the pick and place area Pa of the second pick and place station P2. This means that a component carrier PCB, which has already been populated by the third pick and place station P3, is located in the upstream buffer area Pb of the second pick and place station P2. This is due to the fact that the population of a “previous” component carrier PCB in the pick and place area Pa of the second pick and place station P2 has not yet been completed.

According to the exemplary operating state of the pick and place line 300 shown here, no further component carrier PCB has yet been moved into the third pick and place station P3. This means that the pick and place area Pa of the third pick and place station P3 is not yet occupied by a component carrier PCB.

FIG. 4a illustrates the transport of component carriers PCB in an ideal operation of the pick and place line 300. FIG. 4b illustrates the transport of component carriers during a real operation of the pick and place line 300 that regularly occurs in practice.

As can be seen from FIG. 4a, from the perspective of the component carrier material flow along the direction of transport Td, a first component carrier PCB1 is located in the first pick and place station P1 and is populated with electronic components in its pick and place area Pa. A second component carrier PCB2 is currently being populated in the second pick and place station P2 and a third component carrier PCB3 is currently being populated in the third pick and place station P3.

In the next cycle of the pick and place line 300, the first component carrier PCB1 has been populated and transported out of the first pick and place station P1. The second component carrier PCB2 is now populated in the first pick and place station P1 and the third component carrier PCB3 is populated in the second pick and place station P2. Furthermore, another fourth component carrier PCB4 is populated in the third pick and place station P32.

In the operation of the pick and place line shown in FIG. 4b, there is no component carrier in the second pick and place station P2 (due to a temporary disruption in the component carrier material flow). Consequently, a first component carrier PCB1 is populated in the first pick and place station P1 and a second component carrier PCB2 is populated in the third pick and place station P3.

In the next cycle of the pick and place line 300, the first component carrier PCB1 has been populated and has been transported out of the first pick and place station P1. The pick and place area Pa of the first pick and place station P1 is now free. Furthermore, the second component carrier PCB2 is now in the second pick and place station P2 and is being populated there. In addition, a third component carrier PCB3 has now been transported to the third pick and place station P3 and is being populated in the third pick and place station P3.

In the next but one cycle of the pick and place line 300, the second component carrier PCB2 is located in the first pick and place station P1 and the third component carrier PCB3 is located in the second pick and place station P2. Furthermore, a fourth component carrier PCB4 has now been transported to the third pick and place station P3 and is being populated.

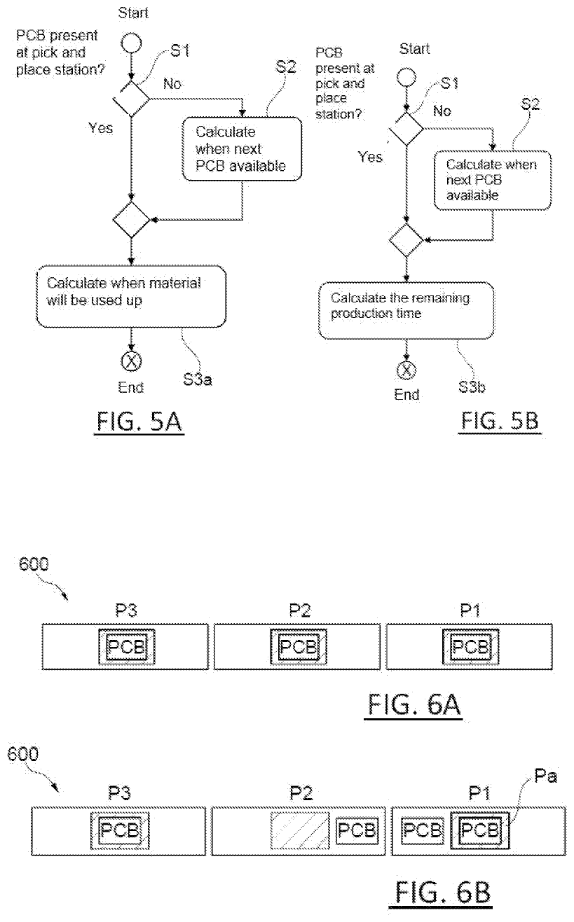

FIG. 5a shows a flow chart of a calculation of the time when the pick and place material available at a pick and place station will (presumably) be used up. This calculation is carried out repeatedly and for all possible feed tracks of the relevant pick and place station in order to always know when new pick and place material will (probably) be required.

The calculation sequence illustrated in FIG. 5a begins at “Start”. In a step S1, a query is made as to whether a component carrier is present at the pick and place station in question. If this is the case, the time when the relevant pick and place material will (probably) be used up is calculated in a step S3a based on the number of pick and place operations that are still required with the pick and place material of the relevant feed track in order to populate this component carrier and the remaining component carriers of the current batch size.

If the query step S1 shows that no component carrier is currently available at the pick and place station, then step S2 calculates when the next component carrier will (presumably) be available in the pick and place area of this pick and place station. For this purpose, at least the position of one or the next component carrier along the transport path, which is located upstream of the pick and place station in question, is taken into account. Once this component carrier availability calculation has been carried out, the result of this component carrier availability calculation is also taken into account in step S3a described above.

FIG. 5b shows a flow chart of a calculation of the time when a next component carrier will (presumably) be present in a pick and place area of a pick and place station. The current operating state of the upstream pick and place station is taken into account for this calculation.

As can be seen from a comparison of FIGS. 5a and 5b, steps S1 and S2 are identical for both calculation sequences. However, in a calculation step S3b of FIG. 5b, the (expected) remaining production time for populating the component carrier currently in the pick and place station in question is reported.

The calculation sequence shown in FIG. 5b can take place or be called up before the calculation sequence shown in FIG. 5a. Furthermore, the calculation sequence of FIG. 5b can also be called up automatically if, for example, no component carrier is currently available in the pick and place station in question.

FIGS. 6a and 6b illustrate the transport of component carriers PCB in an ideal operation of a pick and place line 600 (see FIG. 6a) or in a real operation of the pick and place line 600. During ideal operation, there is exactly one PCB component carrier in each pick and place station P1, P2, P3. Buffer areas of the pick and place stations P1, P2, P3 not shown here are unoccupied.

During real operation of the pick and place line 600 illustrated in FIG. 6b, an unexpected disruption has occurred in the first pick and place station P1. This kind of disruption can occur, for example, if a machine hood has been opened and the pick and place operation in the pick and place station P1 has been interrupted for safety reasons. As a result, the component carrier transport is disturbed in such a way that two component carriers PCB are congested upstream of the still occupied pick and place area Pa of the first pick and place station P1 and thus one buffer area of each of the two pick and place stations P1 and P2 has been occupied.

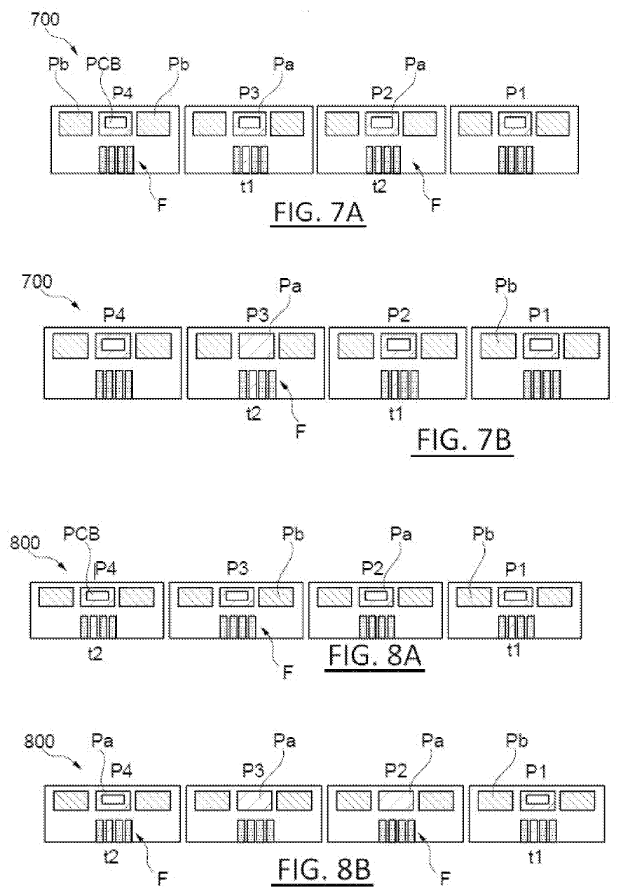

FIGS. 7a and 7b illustrate a sensible change in the sequence for replacing component feeders for a pick and place line 700 with four pick and place stations P1, P2, P3 and P4 based on a comparison with an ideal pick and place operation for a real operation of the pick and place line 700 (with a disrupted transport of component carriers).

In the ideal pick and place operation illustrated in FIG. 7a, there is exactly one component carrier PCB in each pick and place station P1, P2, P3, P4. On the basis of the calculation processes shown in FIGS. 5a and 5b (in each case without step S2), it was determined that the pick and place material in question will initially be used up at a time t1 for a feed track of a component feeder F of the third pick and place station P3 and then at a later time t2 for a feed track of a component feeder F of the second pick and place station P2. Consequently, the replenishment of pick and place material is coordinated in such a way that the pick and place material for the relevant feed track of the third pick and place station P3 is replenished first and then the pick and place material for the relevant feed track of the second pick and place station P2.

In the real pick and place operation illustrated in FIG. 7b, the component carrier transport is (has been) disrupted in such a way that the pick and place area Pa of the third pick and place station P3 is unoccupied. Consequently, it makes sense here to first refill pick and place material at the relevant feed track of the second pick and place station P2 at a time t1 and only then refill pick and place material at the relevant feed track of the third pick and place station P2.

According to the embodiment described here, replenishment with component material is carried out as described above by replacing an “old” component feeder that has been at least partially emptied of component material with a “new” component feeder containing new pick and place material. The component feeder is preferably replaced automatically using a robot.

FIGS. 8a and 8b illustrate a sensible retention of the chronological order for an exchange of component feeders or for a replenishment of pick and place material for a pick and place line 800 with four pick and place stations P1, P2, P3 and P4 for a real operation of the pick and place line 800 (see FIG. 8b), based on a comparison with an ideal pick and place operation of the pick and place line 800 (see FIG. 8a).

Specifically, according to the embodiment shown here, it was determined on the basis of the calculation sequences shown in FIGS. 5a and 5b (in each case without step S2) that the respective pick and place material will initially be used up at a time t1 for a feed track of a component feeder F of the first pick and place station P1 and then at a later time t2 for a feed track of a component feeder F of the fourth pick and place station P4. Consequently, the replenishment of pick and place material is coordinated in such a way that the pick and place material for the relevant feed track of the first pick and place station P1 is replenished first and then the pick and place material for the relevant feed track of the fourth pick and place station P4.

In the state of the pick and place line 800 shown in FIG. 8b, the pick and place areas Pa of the two pick and place stations P2 and P3 have (unfortunately) remained free due to a disrupted transport of component carriers. Nevertheless, the calculation sequences of FIGS. 5a and 5b (including the calculation steps S2), among others, have shown that in this case it makes no sense to change the order of replenishment of pick and place material in order to ensure an uninterrupted supply of pick and place material at the entire pick and place line 800.

It is noted that the term “have” does not exclude other elements and that the word “one or a” does not exclude a plurality. Elements, which are described in connection with different exemplified embodiments, can also be combined. It should also be noted that reference signs in the claims should not be construed as limiting the scope of the claims.

### REFERENCE SIGNS

100 Pick and place line
102 Data processing device
120 Intermediate store
P1 First pick and place station
P2 Second pick and place station
Tp Transport path
Td Direction of transport
F Component feeder
A Pick-up area
C Pick and place material/component belt/electronic components
R Robot
Rf Outward path
Rb Return path
200 Pick and place line
P3 Third pick and place station
P4 Fourth pick and place station
300 Pick and place line
Pa Pick and place area
Pb Buffer area
PCB Component carrier
PCB1 First component carrier
PCB2 Second component carrier
PCB3 Third component carrier
PCB4 Fourth component carrier
S1 First step (query)
S2 Second step (calculation)
S3a/b Third step (calculation)
600 Pick and place line
700 Pick and place line
800 Pick and place line
t1, t2 Time for “Component feeder empty”

1. A method for predicting a time for replenishing pick and place material (C) for a first pick and place station (P1) of a pick and place line (100) comprising at least
(i) the first pick and place station (P1), which is supplied with pick and place material (C) at a first feed track by a first component feeder (F), and
(ii) a second pick and place station (P2) which is supplied with pick and place material (C) at a second feed track by a second component feed device (F), the second pick and place station (P2) being arranged upstream of the first pick and place station (P1) along a transport path (Tp) for component carriers (PCB) to be populated, the method comprising
detecting a current filling level of pick and place material (C) from the first component feeder (F);
determining the planned pick and place operations at least with the pick and place material (C) assigned to the first feed track, which pick and place operations are still required in order to populate all component carriers (PCB) of a current batch production in the first pick and place station (P1);
determining a current position of at least one component carrier (PCB) along the transport path (Tp), which was populated in the second pick and place station (P2) and which is still to be populated in the first pick and place station (P1); and
predicting the time for replenishing pick and place material (C) at the first feed track based on
(i) the detected current filling level, (ii) the determined planned pick and place operations and (iii) the determined current position.

2. The method according to claim 1, wherein
the pick and place material (C) has electronic components, which are held in particular in a component belt or in a component magazine.

3. The method according to claim 1, further comprising
determining a batch size of the current batch production, whereby predicting the time for replenishing pick and place material (C) at the first feed track is also based on the determined batch size.

4. The method according to claim 1, further comprising
determining a length of time for transporting the at least one component carrier (PCB), which has been populated in the second pick and place station (P2) and which is still to be populated in the first pick and place station (P1), from the second pick and place station (P2) to the first pick and place station (P1), wherein
predicting the time for replenishing pick and place material (C) at the first feed track is also based on the determined length of time.

5. The method according to claim 1, further comprising
replenishing the pick and place material (C) at the first feed track ahead of the predicted time.

6. The method according to claim 5, wherein
replenishing the pick and place material (C) comprises
removing the first component feeder (F) from the first transport track, any remaining unused pick and place material (C) is removed together with the first component feeder (F); and
attaching another first component feeder (F) together with new pick and place material (C) to the first feed track, wherein the new pick and place material (C) is located in or on the other first component feeder (F).

7. The method according to claim 6, wherein
the removal of the first component feeder (F) and the attachment of the other first component feeder (F) is automated by means of a robot (R).

8. The method according to claim 1, further comprising
determining a further current position of at least one further component carrier (PCB) along the transport path (Tp), which was populated in a third pick and place station (P3) and which is still to be populated in the first pick and place station (P1) and/or the second pick and place station (P2), wherein
the third pick and place station (P3) is arranged along the transport path (Tp) upstream of the second pick and place station (P2), and wherein predicting the time for replenishing pick and place material (C) at the first feed track is also based on the determined further current position.

9. A method for predicting times for replenishing pick and place material (C) at different predetermined feed tracks of at least one pick and place station (P1) of a pick and place line (100), which has a plurality of pick and place stations which are arranged in succession along a transport path (Tp) of the pick and place line (100) for component carriers to be populated, the method comprising
performing the method according to claim 1, wherein the first feed track is a first predetermined feed track of the pick and place line (100) and the predicted time is a first replenishment time associated with the first predetermined feed track; and
performing the method according to claim 1, wherein the first feed track is a second predetermined feed track of the pick and place line (100) and the predicted time is a second replenishment time associated with the second predetermined feed track.

10. The method according to claim 9, further comprising
determining a chronological order (t1, t2) for (i) a replenishment of pick and place material (C) at the first predetermined feed track and (ii) a replenishment of pick and place material (C) at the second predetermined feed track based on the first replenishment time and the second replenishment time.

11. The method according to claim 10, wherein
the determined chronological order establishes a priority according to which the pick and place material (C) is first replenished at the predetermined feed track to which the earlier replenishment time is assigned.

12. The method according to claim 10, wherein the first replenishment time is prior to the second replenishment time and wherein the method further comprises
replenishing pick and place material (C) at the second predetermined feed track and then
replenishing pick and place material (C) at the first predetermined feed track.

13. A method for determining a chronological order for replenishing pick and place material (C) in at least two feed tracks of a pick and place line (100, 700) which has at least two pick and place stations (P1, P2, P3, P4) for populating component carriers (PCB) wherein each pick and place station (P1, P2, P3, P4) has a pick and place area (Pa) and at least two buffer areas (Pb) for buffering component carriers (PCB), wherein the pick and place areas (Pa) and the buffer areas (Pb) are arranged along a transport path (Tp) of the pick and place line (100, 700) and wherein each upstream pick and place area (Pa) is assigned in each case one of the two buffer areas (Pb), the method comprising
detecting an occupancy state of at least one buffer area (Pb) of the two buffer areas (Pb); and
determining the chronological order based on the at least one detected occupancy state.

14. The method according to claim 13, further comprising
detecting a current filling level of pick and place material (C) at each of the at least two feed tracks; wherein
determining the chronological order is also based on the detected current filling levels.

15. The method according to claim 13, further comprising
determining the planned pick and place operations which are still to be carried out with at least that pick and place material (C) which is assigned to at least one feed track of the at least two feed tracks in order to populate all component carriers (PCB) of a current batch production.

16. A pick and place line (100) for automatically populating component carriers (PCB) with electronic components, which are fed as pick and place material (C) to individual pick and place stations (P1, P2) of the pick and place line (100) on feed tracks by means of a component feeder (F) in each case, the pick and place line (100) having
a data processing device (102) configured to execute a method according to claim 1.
